(19) United States
(12) Patent Application Publication
(10) Pub. No.: US 2013/0256885 A1
(43) Pub. Date: Oct. 3, 2013

(54) Copper Sphere Array Package

(71) Applicant: CONEXANT SYSTEMS, INC., Newport Beach, CA (US)

(72) Inventors: Robert W. Warren, Newport Beach, CA (US); Hyun J. Lee, Aliso Viejo, CA (US); Nic Rossi, Causeway Bay (HK)

(73) Assignee: Conexant Systems, Inc., Newport Beach, CA (US)

(21) Appl. No.: 13/851,906

(22) Filed: Mar. 27, 2013

Related U.S. Application Data
(60) Provisional application No. 61/619,804, filed on Apr. 3, 2012.

(51) Int. Cl. H01L 23/00

(52) U.S. Cl. CPC H01L 24/14; H01L 24/11
USPC 257/738; 438/113

(57) ABSTRACT

Presented is a method for fabricating a semiconductor package, and the associated semiconductor package. The method includes providing a compliant coverlay having a resin film disposed thereon. A plurality of metallic spheres may be placed at predetermined positions in the resin film. A top surface and a bottom surface of the metallic spheres may be flattened. Tamp blocks on opposing sides of the metallic spheres may be used. The resin film may then be cured to permanently set the metallic spheres in the resin film, and the compliant overlay may then be removed. A semiconductor die may then be placed on the plurality of metallic spheres. An encapsulating layer may then be deposited over the semiconductor die, the plurality of metallic spheres, and the resin film. The semiconductor package may then be diced. The method does not include fabricating a metal leadframe for the semiconductor die.

### RELATED APPLICATIONS

The present application claims the benefit of and priority to a pending provisional patent application, titled “Copper Sphere Array Package”, Ser. No. 61/619,804, filed on Apr. 3, 2012, which is hereby incorporated fully by reference into the present application.

### BACKGROUND

As semiconductor technologies become more complex, the number of required input/output (I/O) terminals on semiconductor packages increases. Conventional solutions have included single-row and or multi-row quad flat no-lead (QFN) packages, which may accommodate an increased number of I/O terminals while also providing the flexibility to accommodate one or more rows of terminals with either fixed or variable pitches on the perimeter of a semiconductor package. However, the leadframes utilized in single-row and multi-row QFN packages typically require 4-8 week fabrication lead times, lengthening product development cycle times and time-to-market. In addition, fabrication of the leadframes requires additional logistical planning such as procurement, shipment, incoming inspection, warehousing, inventory management and shelf life control. In addition, because terminals are placed in one or more rows along the perimeter of the semiconductor package the number of terminal pads in a particular row may generally be increased only by reducing terminal pad pitch. However, 0.4 mm is the current minimum terminal pad pitch, thus limiting the number of terminal pads which may be fabricated in a given perimeter length.

### SUMMARY OF THE INVENTION

The present disclosure is directed to a copper sphere array package, substantially as shown in and/or described in connection with at least one of the figures, and as set forth more completely in the claims.

### BRIEF DESCRIPTION OF THE DRAWINGS

FIG. 1 presents an exemplary metallic sphere, in accordance with one implementation of the present application.

FIG. 2A presents a top view of an exemplary semiconductor package, in accordance with one implementation of the present application.

FIG. 2B presents a bottom view of an exemplary semiconductor package, in accordance with one implementation of the present application.

FIG. 3A presents a progressive cross-sectional view of a semiconductor package having an uncured resin film disposed on a compliant coverlay, in accordance with one implementation of the present application.

FIG. 3B presents a progressive cross-sectional view of a semiconductor package having a plurality of metallic spheres at predetermined positions in the resin film, in accordance with one implementation of the present application.

FIG. 3C presents a progressive cross-sectional view of a semiconductor package having flattened metallic spheres, in accordance with one implementation of the present application.

FIG. 3D presents a progressive cross-sectional view of a semiconductor package having flattened metallic spheres and a cured resin layer, in accordance with one implementation of the present application.

FIG. 3E presents a progressive cross-sectional view of a semiconductor package having a semiconductor die, in accordance with one implementation of the present application.

FIG. 3F presents a progressive cross-sectional view of a semiconductor package having an encapsulating layer over the semiconductor die, in accordance with one implementation of the present application.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

Various implementations of the present application provide for multiple metallic spheres, which may act as inner and outer terminals of a semiconductor package in lieu of metal leadframes or laminate substrates. In addition, because such metallic spheres may be positioned and fixed in place utilizing assembly equipment, the need to order design-specific materials in advance is eliminated, shortening assembly build cycle times by one to two months. By pre-stocking an inventory of just a few sphere sizes any device may be assembled or packaged into a copper sphere array package (CSAP) within approximately 48 hours, rather than the 6 to 8 weeks required for conventional multi-row QFN processes. Such time, procedure and inventory requirement reductions may result in lower cost packages as compared to conventional multi-row QFN processes. In addition, because the metallic spheres are compatible with high volume automated assembly, semiconductor package fabrication cost may be further reduced.

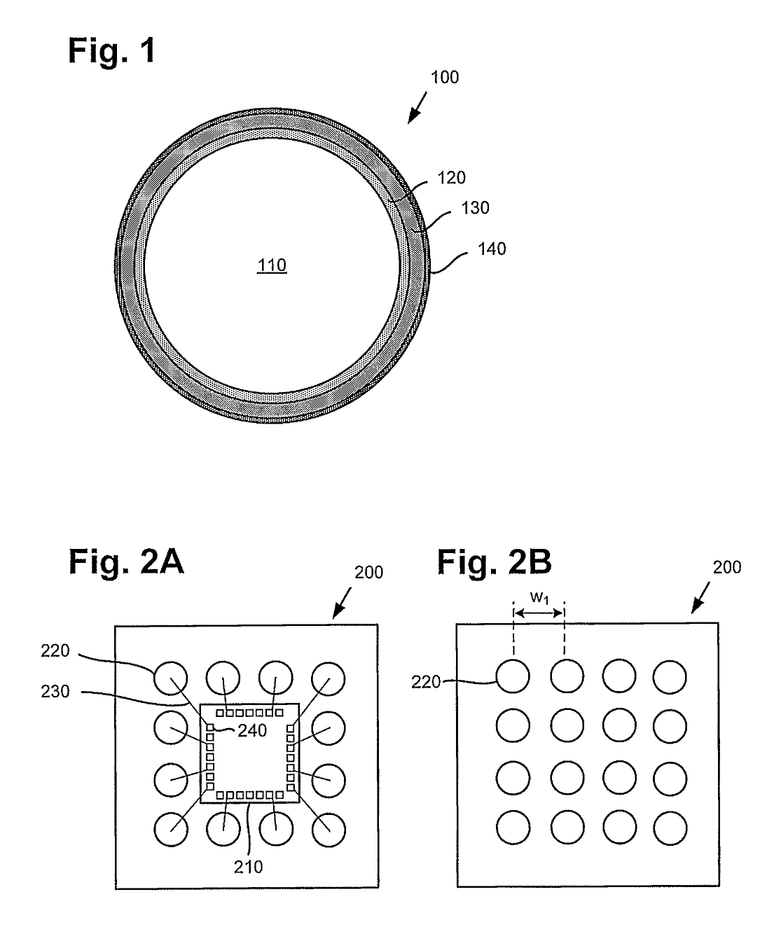

FIG. 1 presents an exemplary metallic sphere, in accordance with one implementation of the present application. Specifically, FIG. 1 presents metallic sphere 100 including metallic core 110, which may be copper or any other electrically conductive metal. An electro-migration barrier layer 120, may be applied to metallic core 110. Electro-migration barrier 120 may be nickel or any other electrically conductive material providing a suitable electro-migration barrier for metallic core 110. In order to ensure compatibility with wire bonding or solder bonding, bondable layer 130 is applied over electro-migration barrier 120. Bondable layer 130 may be palladium or any other electrically conductive material that allows for reliable wire bonding or solder bonding connections. To prevent oxidation, a thin oxidation barrier 140 may be applied to bondable layer 130. Oxidation barrier 140 may be a thin gold flash or any other electrically conductive material providing a low resistance oxidation barrier.

FIGS. 2A and 2B present top and bottom views, respectively, of an exemplary semiconductor package, in accordance with one implementation of the present application. Specifically, FIG. 2A presents a top view of semiconductor package 200 including a plurality of metallic spheres 220, similar to metallic sphere 100 shown in FIG. 1, disposed on the top surface of semiconductor package 200. Each of metallic spheres 220 may be electrically connected to one or more conductive pads 240 of semiconductor die 210 by one or more electrical connections 230. Metallic spheres 220 may provide a low inductance electrical path as well as high thermal dissipation for semiconductor package 200. Consequently, metallic spheres 220 may additionally act as thermal spheres for the purpose of enhanced thermal dissipation.

FIG. 2B presents a bottom view of semiconductor package 200 having a plurality of metallic spheres 220 disposed in an array directly on the bottom surface of semiconductor package 200. Metallic spheres 220 may be evenly spaced or may have an irregular pitch from metallic sphere to metallic sphere. For example, attachment of metallic spheres 220 directly to semiconductor package 200 at a reduced pitch w₁ may allow greater thermal dissipation than conventional QFNs. Semiconductor package 200 may then be attached to one or more other semiconductor packages or devices through soldering and wire bonding, or alternatively, utilizing a flip chip bonding method.

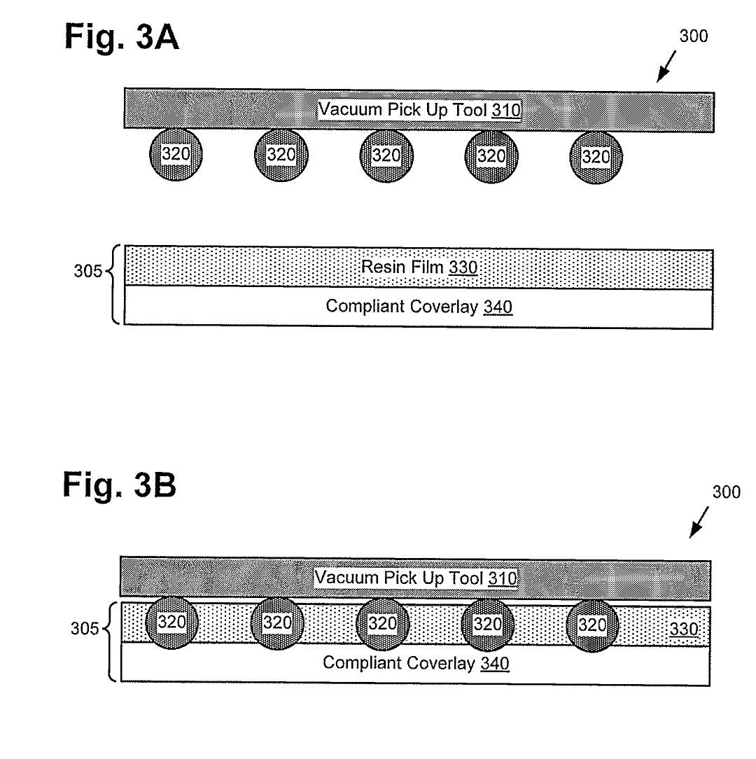

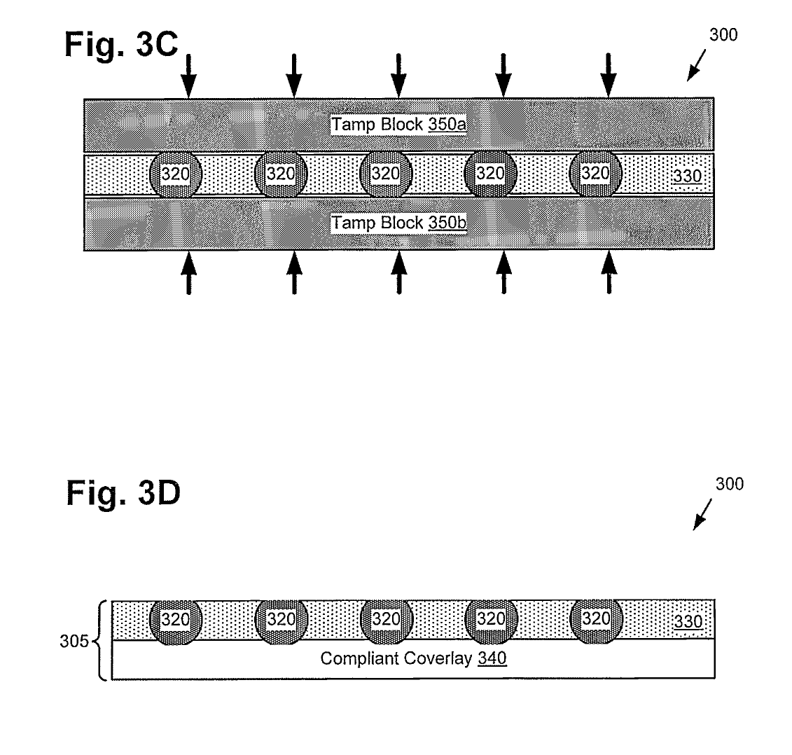

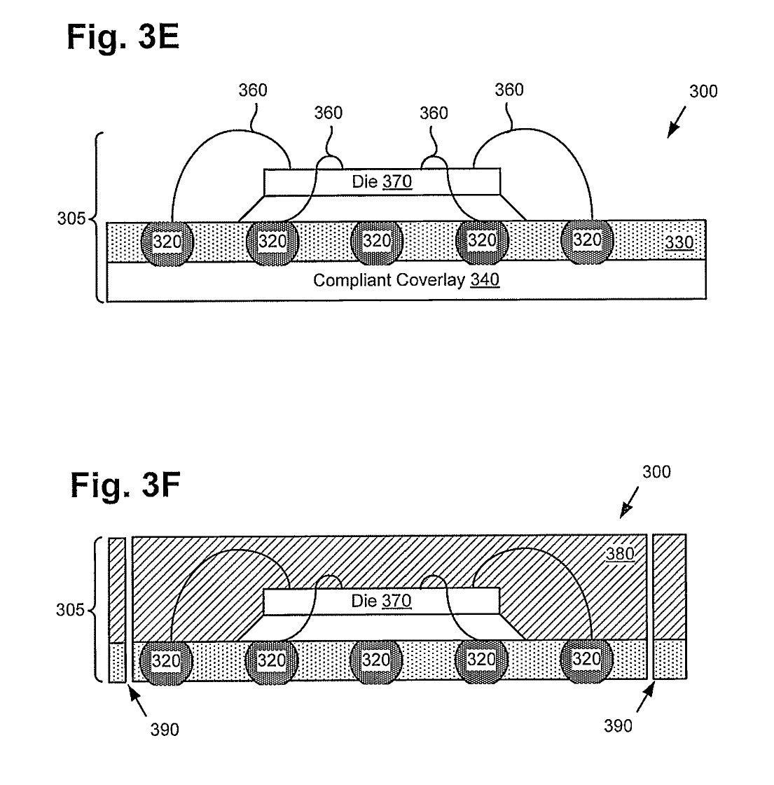

FIGS. 3A through 3F present progressive cross-sectional views of a semiconductor package during fabrication, in accordance with one implementation of the present application. Specifically, FIG. 3A presents system 300 including semiconductor package 305 having an uncured resin film 330 disposed on compliant coverlay 340. Compliant coverlay 340 may be a polyimide film. However, compliant coverlay 340 is not so limited and may be any suitable coverlay material. System 300 may also include vacuum pick up tool 310 which may be configured to pick and place a plurality of metallic spheres 320 at predetermined positions on or in resin film 330.

FIG. 3B presents semiconductor package 305 having the plurality of metallic spheres 320 at predetermined positions in resin film 330, where placing is handled by lowered vacuum pick up tool 310. Once the plurality of metallic spheres 320 are placed at desired locations, the surfaces of metallic spheres 320 may be flattened to provide a stable surface for subsequent electrical connection, such as wire bonding or flip chip bonding.

FIG. 3C presents semiconductor package 305 where top and bottom surfaces of metallic spheres 320, disposed in resin layer 330, are flattened utilizing tamp blocks 350a and 350b applied to opposing sides of metallic spheres 320. Appropriate pressure may be applied to metallic spheres 320 until their surfaces become flattened to a desired level. Though tamp blocks 350a and 350b may be applied to metallic spheres 320 while still disposed in resin layer 330 and over compliant coverlay 340, each of metallic spheres 320 may be flattened at both a top surface and a bottom surface of each metallic sphere. In addition to providing electrical and thermal connections, the metallic spheres may provide an inherent standoff between semiconductor package 305 and any subsequently attached printed circuit boards, improving board-level reliability. Once metallic spheres 320 are partially flattened, resin layer 330 may be cured to permanently set metallic spheres 320 in place.

FIG. 3D presents semiconductor package 305 having flattened metallic spheres 320 and cured resin layer 330, in accordance with one implementation of the present application. Resin layer 330 may be cured by any appropriate method, including but not limited to exposure to a curing agent or exposure to sufficient heat and/or pressure to cause curing. Anytime after resin layer 330 is cured, compliant coverlay 340 may be removed by any appropriate method. Once resin layer 330 has been cured, semiconductor die 370 may be placed on metallic spheres 320 and resin layer 330 for electrical and/or thermal connection.

FIG. 3E presents semiconductor package 305, in accordance with one implementation of the present application. Semiconductor die 370 may be connected at various points to one or more of metallic spheres 320 through electrical connections 360, which may be conductive wires connected by wire bonding, for example. Once semiconductor die 370 has been attached, encapsulation and dicing may take place.

FIG. 3F presents semiconductor package 305 having encapsulating layer 380 over semiconductor die 370. Encapsulating layer 380 may include any suitable encapsulating material. Additionally, the entire semiconductor device may be diced. FIG. 3F shows dicing lines 390, which may serve to separate adjacent semiconductor packages from one another according to predetermined dimensions.

Thus, the present inventive concepts provide for devices, systems and methods that eliminate the need for semiconductor leadframes or substrates and the associated 4 to 8 week material lead time. Implementations of the present application further provide a capability of fabricating an increased number of I/O terminals each having stable surfaces for wirebonding with low inductance and high thermal dissipation properties. Implementations additionally provide an inherent standoff with attached boards.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

What is claimed is:

1. A method for fabricating a semiconductor package, said method comprising:
providing a compliant coverlay having a resin film disposed thereon;
placing a plurality of metallic spheres at predetermined positions in said resin film;
flattening a top surface and a bottom surface of each of said plurality of metallic spheres;

2. The method of claim 1, further comprising curing said resin film to permanently set said plurality of metallic spheres in said resin film.

3. The method of claim 1, further comprising placing a semiconductor die on said plurality of metallic spheres.

4. The method of claim 1, further comprising depositing an encapsulating layer over said semiconductor die, said plurality of metallic spheres, and said resin film.

5. The method of claim 1, further comprising removing said compliant coverlay from said resin film.

5. The method of claim 1, further comprising dicing said semiconductor package.

6. The method of claim 1, wherein said flattening said top surface and said bottom surface of each of said plurality of metallic spheres is achieved by applying tamp blocks to opposing sides of said plurality of metallic spheres.

7. The method of claim 1, wherein said placing said plurality of metallic spheres at said predetermined positions forms an evenly spaced array in said resin film.

8. The method of claim 1, wherein said placing said plurality of metallic spheres at said predetermined positions forms an array having an irregular pitch between metallic spheres in said resin film.

9. The method of claim 1, wherein said method does not include fabricating a metal leadframe for said semiconductor die.

10. The method of claim 1, wherein each of said plurality of metallic spheres further include one or more of an electro-migration barrier layer, a bondable layer and/or an oxidation barrier layer formed around a metallic core.

11. A semiconductor package comprising:
a removable compliant coverlay having a resin film disposed thereon;
a plurality of metallic spheres disposed at predetermined positions in said resin film, each of said plurality of metallic spheres having a flattened top surface and a flattened bottom surface.

12. The semiconductor package of claim 11, further comprising a semiconductor die disposed on said plurality of metallic spheres.

13. The semiconductor package of claim 12, further comprising an encapsulating layer over said semiconductor die, said plurality of metallic spheres, and said resin film.

14. The semiconductor package of claim 11, wherein said plurality of metallic spheres form an evenly spaced array in said resin film.

15. The semiconductor package of claim 11, wherein said plurality of metallic spheres form an array having an irregular pitch between metallic spheres in said resin film.

16. The semiconductor package of claim 11, wherein said semiconductor package does not include a metal leadframe.

17. The semiconductor package of claim 11, wherein each of said plurality of metallic spheres comprises an electro-migration barrier layer surrounding a metallic core.

18. The semiconductor package of claim 11, wherein each of said plurality of metallic spheres comprises a bondable layer surrounding said metallic core.

19. The semiconductor package of claim 11, wherein each of said plurality of metallic spheres comprises an oxidation barrier layer surrounding said metallic core.

20. The semiconductor package of claim 11, wherein said plurality of metallic spheres provide one or more inner terminals and/or one or more outer terminals for said semiconductor package.
